(19) United States
(12) Patent Application Publication
(10) Pub. No.: US 2009/0102320 A1
(43) Pub. Date: Apr. 23, 2009

(54) PIEZOACTUATOR

(76) Inventor: Patrick Mattes, Stuttgart (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 12/299,831

(22) PCT Filed: May 11, 2007
(86) PCT No.: PCT/EP07/54592

§ 371 Date: Nov. 6, 2008

(30) Foreign Application Priority Data
May 17, 2006 (DE) 10-2006-022-997.5

(51) Int. Cl. H01L 41/00

(52) U.S. Cl. 310/328

(57) ABSTRACT

A piezoactuator includes a piezoelement of a multilayer construction of piezolayers, with internal electrodes arranged between the piezolayers alternately having a differing polarity of an electrical voltage applied to them. An actuator base and an actuator head and an insulation medium surrounding at least the piezolayers of the piezoelement are present. The surface of the piezoelement is provided with a first electrical insulation layer. The piezoactuator has at least one layer of a metallic film wound around it at least in the region of the piezoelement. A layer of a plastic is applied to the film and in a manner overlying the connecting locations with respect to the actuator head and with respect to the actuator base.

The invention relates to an at least partially encased piezoelectric actuator, for example around which fluid media flow, with the defining characteristics of the preamble to the main claim.

### PRIOR ART

It is intrinsically known that the above-mentioned piezoelectric actuator can be constructed using a piezoelectric element in such a way that by utilizing the so-called piezoelectric effect it is possible to carry out a valve needle stroke control or the like. The piezoelectric element is composed of a material with a suitable crystalline structure so that when an external voltage is applied, a mechanical reaction of the piezoelectric element occurs. which, depending on the crystalline structure and the application region of the electric voltage, represents a compression or a tension in a predeterminable direction. Piezoelectric actuators of this kind are suitable, for example, for applications in which stroke motions occur with powerful actuation forces and at high clock frequencies.

DE 10026005 A1, for example, has disclosed using a piezoelectric actuator of this kind as a component of a piezo injector, which component can be used for triggering the nozzle needle in injectors for the injection of fuel into the combustion chamber of an internal combustion engine. In this piezoelectric actuator, a piezoelectric element is constructed in the form of a stack composed of a plurality of electrically interconnected piezoceramic layers and is held in a prestressed fashion between two stops by means of an actuator foot and an actuator head. Each piezoceramic layer serving as a piezoelectric layer is sandwiched between two internal electrodes via which an electrical voltage can be applied from the outside. In reaction to this electrical voltage, the piezoceramic layers then each execute small respective stroke movements in the direction of the potential gradient, which add up to constitute the overall stroke of the piezoelectric actuator. This overall stroke can be changed via the magnitude of the applied voltage and can be transmitted to a mechanical actuating element.

Such known arrangements are frequently used as so-called common rail systems for delivering fuel in direct-injection diesel engines. In these systems known as common rail injectors, the injection pressure can be easily adapted to the load and speed of the internal combustion engine.

These common rail injectors can be embodied so that there is a nozzle needle indirectly controlled by the piezoelectric actuator; the piezoelectric actuator is directly or indirectly surrounded by the pressure of the fuel and only a hydraulic coupling chamber is provided between the nozzle needle and the piezoelectic actuator.

In particular in such injection systems, it is important that the relatively sensitive piezoelectric actuator is embodied in a media-resistant fashion inside a holding body. The piezoelectric actuator in this case must be resistant to the various fuels and also to the changing pressures and temperatures. Furthermore, during assembly and transport, a secure handling is required as well as a protection from mechanical shock or pressure, particularly with regard to the electrical insulation.

In order to achieve an electrical and mechanical insulation of the piezoelectric actuator, it is often proposed that the piezoelectric actuator module be enclosed in a casing. In order to avoid the disadvantages described above, DE 10230032 A1 has disclosed an arrangement with a piezoelectric actuator around which fluid media flow, in which the ceramic layers of the piezoelectric element are cast into an insulating compound that can change shape and that is in turn inserted as a sleeve into a metallic housing casing that is sealed in relation to the medium at its sides and at its upper and lower ends.

Of particular note in this connection is primarily the problem of sealing a coating material of the piezoelectric actuator and possibly a sleeve at the end points on an actuator foot, an actuator head, and possibly a holding body—as a rule composed of steel—to protect the arrangement from mechanical influences here as well. Since the piezoelectric actuator and the coating or casing must absorb additional mechanical expansion forces by means of its stroke, metal sleeves are also used in the conventional way in connection with diaphragms. The known arrangements, however, are complex and therefore cost-intensive in their manufacture.

### DISCLOSURE OF THE INVENTION

The invention is based on a piezoelectric actuator described at the beginning, with a piezoelectric element that is composed of a multilayered structure of piezoelectric layers; internal electrodes situated between the piezoelectric layers in the direction of the layer structure of the piezoelectric element are acted on in alternation with different polarities of an electrical voltage, having an actuator foot, an actuator head, and an insulating medium encompassing at least the piezoelectric layers. According to the invention, the surface of the piezoelectric element is advantageously provided with a first electrical insulation layer. In addition, the piezoelectric actuator, possibly together with its actuator foot and actuator head held together with an axial prestressing force, is wrapped with at least one layer of a metallic foil and then a layer of a plastic is applied, which covers the foil and overlaps the attachment points of the piezoelectric element to the actuator foot and the actuator head.

The invention consequently produces an inexpensive-to-manufacture piezoelectric actuator, which, as mentioned at the beginning, can be a component of a piezo injector for a fuel injection system in an internal combustion engine in which fuel flows around the plastic. The proposed casing makes the piezoelectric actuator according to the invention extremely media-resistant and also assures a safe handling during transport and assembly.

According to a particularly advantageous embodiment, protruding ends of the metallic foil converge in an extension at least in the region of the actuator foot and can therefore be tightly compressed into an essentially cylindrical form that extends further in the axial direction. In this case, it is also advantageous if a central, axial bore is provided in the actuator foot, into which the converging, united foil ends are inserted.

The plastic, which is partially elastic for the given mechanical and thermal strain in this case and is applied as a final layer, can simply be composed of a plastic extrusion coating that has solid particles mixed into it. In this instance, the plastic extrusion coating can preferably be a PA66 plastic or the like and the solid particles can be composed, for example, of metal or silicon, particularly in order to improve the thermal conductivity in the plastic.

The first electrical insulation layer on the surface of the piezoelectric element is preferably an electrically insulating lacquer applied in an intrinsically known fashion with a thickness of approx. 100 to 200 □m. The metallic foil wound onto it can, for example, have a thickness of approx. 10 to [symbol] □m.

Depending on the respective use of the piezoelectric actuator in a subassembly, the piezoelectric actuator can have a round or rectangular cross section.

### BRIEF DESCRIPTION OF THE DRAWINGS

Exemplary embodiments of the piezoelectric actuator according to the invention will be explained in conjunction with the drawings.

FIG. 1 shows a section through a piezoelectric actuator, which is enclosed in a foil and a plastic extrusion coating and has an actuator head and actuator foot,

FIG. 2 shows a section through the piezoelectric actuator according to FIG. 1, with a rectangular cross section, and

FIG. 3 shows a section through a piezoelectric actuator which is enclosed in a foil and a plastic extrusion coating, with protruding ends of the foil united in a bore of the actuator foot.

### EMBODIMENT OF THE INVENTION

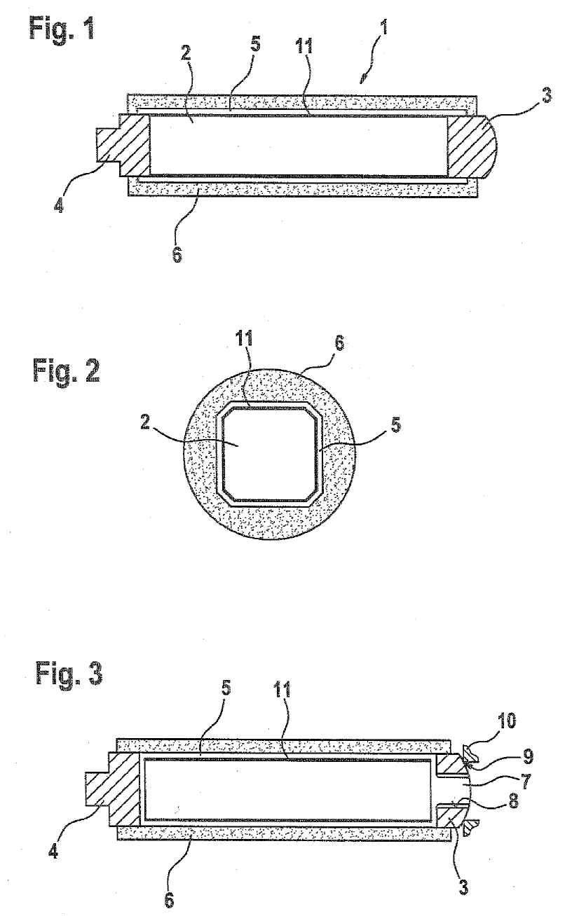

FIG. 1 shows a piezoelectric actuator 1 that can be used, for example, for needle stroke control in a fuel injection system of an internal combustion engine. A piezoelectric element 2 is a component of the piezoelectric actuator 1, which also has an actuator foot 3 and an actuator head 4, mostly composed of steel. FIG. 2 shows that the piezoelectric actuator 1 has a rectangular cross section; depending on the practical application, however, it can also have a round or otherwise adapted cross section.

The piezoelectric element 2 contains internal electrodes not explicitly shown here, which are contacted by means of external electrodes and by means of electrical supply lines, likewise not shown here, which are routed through the actuator foot 3. When the piezoelectric actuator 1 is actuated through an application of a voltage to the internal electrodes, a mechanical arrangement that is situated axially beyond the actuator head 4 in this case can be actuated in such a way that in the above-mentioned practical application, it is possible to open a nozzle port of the injection system.

As a rule, the piezoelectric actuator 1 is built into a holding body or injector body that is not shown here; the fuel is conveyed past the piezoelectric actuator 1 through the inner chamber of the injector body. This fuel can then be injected—for example in a so-called common rail system at the rail pressure mentioned in the introduction to the specification or at another predeterminable pressure—into the combustion chamber of an internal combustion engine that is not shown here.

In order to protect the piezoelectric actuator 1 from the fuel flowing around it and from other damaging influences, the piezoelectric actuator 1 is provided with the casing according to the invention, in which first, the surface of the piezoelectric element 2 here is provided with a first electrical insulation layer 11, which is composed of electrically insulating lacquer with a thickness of approx. 100 to 200 □m.

The piezoelectric actuator is also wrapped with at least one layer of a metallic foil 5, for example with a thickness of approx. 10 to [symbol] □m, which is wound onto the piezoelectric actuator, onto the piezoelectric element 2, and at least partially onto the actuator foot 3 and the actuator head 4. In this connection, the piezoelectric element 2 should be held together and aligned with the actuator foot 3 and the actuator head 4 with a prestressing force in the axial direction. A layer of plastic 6 is applied, which covers the foil 5 and overlaps it.

The preferably partially elastic plastic 6 here, which is applied as the final coating, can be simply composed of a plastic extrusion coating, for example PA66, which has solid particles mixed into it, for example composed of metal or silicon. With an appropriate selection of a plastic extrusion coating and of the manufacturing apparatus used for it, it is even possible to dispense with the above-mentioned prestressing force, for example with tubular or helical springs, between the elements of the piezoelectric actuator 1 during the wrapping and the extrusion coating.

FIG. 2 shows a modified exemplary embodiment in which the piezoelectric element 2 is almost completely wrapped and protruding ends 7 of the foil 5 converge in the region of the actuator foot 3 and can then be tightly compressed into an essentially cylindrical form that extends axially into a bore 8 in the actuator foot 3. Here, too, a plastic 6 is applied in the form of a plastic extrusion coating. FIG. 2 also schematically shows how the actuator foot 3 rests with sealing edges 9 against a holding body 10 that is only indicated here.

1-9. (canceled)

10. A piezoelectric actuator, comprising:
a piezoelectric element;
an actuator foot;
an actuator head;
an insulating medium encompassing at least the piezoelectric element;
a first electrical insulation layer provided on an outer surface of the piezoelectric element;
at least one layer of a metallic foil wrapped on the piezoelectric actuator, at least in the region of the piezoelectric element; and
a layer of a plastic applied, which covers the foil and overlaps connecting points between the piezoelectric element and the actuator foot and actuator head.

11. The piezoelectric actuator as recited in claim 10, wherein at least in the region of the actuator foot, the ends of the metallic foil converge in an extension, and a central axial bore is provided in the actuator foot into which the extension of the converging ends of the foil are inserted.

12. The piezoelectric actuator as recited in claim 10, wherein the plastic is composed of a plastic extrusion coating that has solid particles mixed into it.

13. The piezoelectric actuator as recited in claim 11, wherein the plastic is composed of a plastic extrusion coating that has solid particles mixed into it.

14. The piezoelectric actuator as recited in claim 12, wherein the plastic of the plastic extrusion coating is composed of PA66.

15. The piezoelectric actuator as recited in claim 13, wherein the plastic of the plastic extrusion coating is composed of PA66.

16. The piezoelectric actuator as recited in claim 12, wherein the solid particles are composed of metal or silicon.

17. The piezoelectric actuator as recited in claim 13, wherein the solid particles are composed of metal or silicon.

18. The piezoelectric actuator as recited in claim 10, wherein the first electrical insulation layer on the surface of the piezoelectric element is an electrically insulating lacquer with a thickness of approx. 100 to 200 micrometers.

19. The piezoelectric actuator as recited in claim 11, wherein the first electrical insulation layer on the surface of the piezoelectric element is an electrically insulating lacquer with a thickness of approx. 100 to 200 micrometers.

20. The piezoelectric actuator as recited in claim 12, wherein the first electrical insulation layer on the surface of the piezoelectric element is an electrically insulating lacquer with a thickness of approx. 100 to 200 micrometers.

21. The piezoelectric actuator as recited in claim 10, wherein the piezoelectric actuator has a round cross section.

22. The piezoelectric actuator as recited in claim 11, wherein the piezoelectric actuator has a round cross section.

23. The piezoelectric actuator as recited in claim 12, wherein the piezoelectric actuator has a round cross section.

24. The piezoelectric actuator as recited in claim 10, wherein the piezoelectric actuator (1) has a rectangular cross section.

25. The piezoelectric actuator as recited in claim 11, wherein the piezoelectric actuator (1) has a rectangular cross section.

26. The piezoelectric actuator as recited in claim 12, wherein the piezoelectric actuator (1) has a rectangular cross section.

27. A use of a piezoelectric actuator as recited in claim 10, wherein the piezoelectric actuator is a component of a piezo injector for a fuel injection system of an internal combustion engine and the fuel flows around the plastic layer.

28. A use of a piezoelectric actuator as recited in claim 11, wherein the piezoelectric actuator is a component of a piezo injector for a fuel injection system of an internal combustion engine and the fuel flows around the plastic layer.

29. A use of a piezoelectric actuator as recited in claim 12, wherein the piezoelectric actuator is a component of a piezo injector for a fuel injection system of an internal combustion engine and the fuel flows around the plastic layer.
